(19) United States
(12) Patent Application Publication
(10) Pub. No.: US 2006/0071303 A1
(43) Pub. Date: Apr. 6, 2006

(54) Film substrate of a semiconductor package and a manufacturing method

(76) Inventors: Chung-Sun Lee, Gyeonggi-do (KR); Yong-Hwan Kwon, Gyeonggi-do (KR); Sa-Yoon Kang, Seoul (KR); Kyoung-Sei Choi, Chungcheongnam-do (KR)

Correspondence Address: MARGER JOHNSON & MCCOLLOM, P.C., 210 SW MORRISON STREET, SUITE 400, PORTLAND, OR, 97204, US

(21) Appl. No.: 11/218,260

(22) Filed: Aug. 31, 2005

(30) Foreign Application Priority Data
Oct. 6, 2004 (KR) 2004-79514

(51) Int. Cl. H01L 23/58

(52) U.S. Cl. 257/643

(57) ABSTRACT

Embodiments of the present invention are directed to a film substrate of a semiconductor package. The film substrate of the semiconductor package comprises a thin film insulating substrate and a thin copper circuit pattern. An inter-pattern groove between the thin copper circuit patterns is formed by laser etching. Accordingly, the embodiment improves electrical contact between the film substrate and a semiconductor chip mounted thereon, and improves the manufacturing process for the film substrate by adopting a simple laser machining to form the thin copper circuit pattern in lieu of a traditional wet-etching process that undergoes complex lithography steps.

### CLAIM FOR PRIORITY

This application claims priority from Korean Patent Application No. 2004-79514 filed on Oct. 6, 2004 in the Korean Intellectual Property Office (KIPO), the entire contents of which are hereby incorporated by reference.

### BACKGROUND OF THE INVENTION

1. Field of the Invention

The present invention relates to a film substrate of semiconductor packages and its manufacturing method, and, more particularly, to a structure and manufacturing method of a film substrate of a COF (chip on film) package where a semiconductor chip is stacked on the film substrate that is made of a resin material like polyimide.

2. Description of the Related Art

Rapid technical advances in semiconductor devices toward higher integration and thinness have brought advances in assembly technologies for manufacturing semiconductor packages. As portable electronic equipment become smaller and lighter their market demand is rapidly expanding worldwide. For example, in the liquid crystal display panel market, the demand for driver integrated circuit chips to support colors and moving pictures has caused an explosive increase in the number of contact pads per unit chip. Accordingly, semiconductor packages utilizing a film-type mounting substrate have been developed to achieve fine pitch, miniaturization, and thinness.

These semiconductor packages utilizing film-type mounting substrates are largely classified into TAB (Tape Automated Bonding) and COF (Chip On Film) packages. The COF package is a package that has a gold (Au) bump-equipped semiconductor chip stacked on a film substrate possessing an insulating substrate like polyimide.

FIG. 1 is a schematic top view of a conventional COF semiconductor package. FIG. 2 is a partial cross-sectional view showing the semiconductor package taken along the line I-I′ in FIG. 1.

As shown in FIG. 1, the conventional COF semiconductor package 10 utilizes a polyimide insulating substrate 11 as a mounting substrate, on which a thin copper circuit pattern 13a implementing a circuit is formed. A semiconductor chip 1 is mounted on the insulating substrate 11 via bump bonding. Namely, bumps 2 are preformed on the semiconductor chip 1 as shown in FIG. 2, and then the chip 1 is mounted on the film substrate by connecting the bumps 2 to the thin copper circuit pattern 13a.

Because of the thinness of the film, fine line widths and gaps can be obtained in the thin copper circuit pattern. This COF semiconductor package utilizing a film substrate has a structural advantage in achieving fine pitch, thinness, and miniaturization. In addition, the COF semiconductor package has another advantage in the process of mounting chips and electrical connections because bump bonding can be performed in a group while wire bonding between chip pads and leadframe's leads is performed individually.

FIGS. 3A to 3J are cross-sectional views showing a manufacturing process for the film substrate of the conventional COF semiconductor package. Hereinafter, the manufacturing process is explained with reference to FIGS. 3Aa to 3J.

A polyimide insulating substrate 11 is provided as shown in FIG. 3A.

As shown in FIG. 3B, a thin-film metal seed layer 12 is formed on the polyimide insulating substrate 11 by sputtering. The metal seed layer 12 in this embodiment is made with nickel (Ni) or copper (Cu).

Next, as shown in FIG. 3C, a copper metal layer 13 is formed by plating copper on the metal seed layer (12 in FIG. 3B). For the convenience of illustration, the copper metal layer 13 is drawn as if it includes the metal seed layer 12, which is negligible compared to the thickness of the copper metal layer 13. Here, the thickness t1 of the copper metal layer 13 is about 8 μm.

Next, as shown in FIG. 3D, a photoresist layer 14 is formed on the copper metal layer 13.

As shown in FIG. 3E, a mask pattern 15 is then placed on the photoresist layer 14 to form a thin copper circuit pattern (13a in FIG. 3G).

As shown in FIG. 3F, a photoresist pattern 14a is formed on the copper metal layer 13 by exposing and developing a photoresist.

Continuing the process, as shown in FIG. 3G, the thin copper circuit pattern 13a is formed by wet etching, and then the photoresist pattern (14a in FIG. 3F) is stripped off. During this manufacturing process, the wet etching creates a trapezoidal, not a rectangular, form owing to over-etching at the pattern's upper edges. Consequently, this narrowed width W1 of the upper surface F1 of the thin copper circuit pattern 13a leads to problems that will be explained later.

FIG. 3H is a cross-sectional view showing the portion of FIG. 3G taken along the line II-II′. As shown in FIG. 3H, the thin copper circuit pattern 13a is stacked on the polyimide insulating substrate 11, and the central area of the upper surface of the polyimide insulating substrate 11 is exposed.

As shown in FIG. 3I, a solder resist layer 15 is formed on the thin copper circuit pattern 13a. The solder resist layer 15 may be formed on the area of the polyimide insulating substrate 11 exposed between the thin copper circuit patterns 13a (K1 in FIG. 3G), but it is not formed on the area K2 to which the bump of the semiconductor chip will be connected.

Finally, as shown in FIG. 3J, a plating layer 16 is formed on the exposed area K2 of the thin copper circuit pattern 13a. The plating layer 16 is provided to improve characteristics of the contact with the bump of a semiconductor chip, and is commonly plated with tin (Sn). With this, the manufacturing process for the film substrate of the conventional COF semiconductor package is complete. On the plating layer 16, as shown in FIG. 2, the bump 2 of the semiconductor chip 1 is mounted.

FIG. 4 is a partial cross-sectional view showing the semiconductor package taken along the line III-III′ in FIG. 2.

As shown in FIG. 4, the width W2 of the upper part facing the plating layer 16 is significantly narrower than the width W3 of the lower part of the plated thin copper circuit pattern 13a. This is caused by the over-etching by the wet-etching method of the copper metal layer, as explained above. The angle of inclination D1 between a vertical line and the thin copper circuit pattern may be as large as 45˜60°. Consequently, as shown in FIG. 4, the contact area between the bump 2 and the plating layer 16 on the thin copper circuit pattern 13a is reduced. This causes a poor electrical contact between the bump 2 and the thin copper circuit pattern 13a manufacturing efficiency may also be reduced owing to a complex lithography process including photoresist coating, exposing, developing, etching, and photoresist stripping to form the thin copper circuit pattern via wet-etching.

To overcome this over-etching problem, dry etching instead of wet-etching may be considered. However, equipment and gases for dry etching are very expensive, and increase operating costs of the manufacturing process. It is also difficult to achieve a fine pitch in the thin copper circuit pattern owing to the technical difficulty of applying dry etching to copper (Cu).

### SUMMARY OF THE INVENTION

To solve the problems described above, embodiments of the present invention provide a film substrate of semiconductor packages and a manufacturing method thereof that are capable of not only simplifying manufacturing process but also improving characteristics of the electric contact between the thin copper circuit pattern and the bump, acting as an external interface of the semiconductor chip.

According to the present invention, a film substrate of a semiconductor package comprises a thin film insulating substrate made with resin material, and a circuit pattern formed on the thin film insulating substrate. The depth of an inter-pattern groove between the circuit patterns is greater than the thickness of the circuit pattern.

According to an embodiment of the present invention, a method of manufacturing a film substrate of a semiconductor package comprises providing a thin film insulating substrate made with resin material, forming a metal layer on the thin film insulating substrate, and forming a circuit pattern by treating the metal layer with a laser.

### BRIEF DESCRIPTION OF THE DRAWINGS

FIG. 1 is a schematic top view showing a conventional COF semiconductor package.

FIG. 2 is a partial cross-sectional view showing the semiconductor package taken along the line I-I′ in FIG. 1.

FIGS. 3A to 3J are cross-sectional views showing a manufacturing process for a film substrate of the conventional COF semiconductor package.

FIG. 4 is a partial cross-sectional view showing the semiconductor package taken along the line III-III′ in FIG. 2.

FIGS. 5A to 5G are cross-sectional views showing a manufacturing process for a film substrate of semiconductor packages according to the present invention.

FIG. 6 is a schematic view illustrating a laser machining apparatus for manufacturing film substrates of semiconductor packages according to the present invention.

FIG. 7A is a schematic view illustrating a laser machining in the method of manufacturing film substrates of semiconductor packages according to the present invention.

FIG. 7B is a top view showing an irradiation region taken along the line M3-M3′ in FIG. 7A.

FIG. 8A is a cross-sectional view showing an embodiment of a semiconductor package that has a semiconductor chip stacked on the film substrate of semiconductor packages according to the present invention.

FIG. 8B is a cross-sectional view showing the portion of the semiconductor package taken along the line V-V′ in FIG. 8A.

FIG. 9A is a cross-sectional view showing another embodiment of a semiconductor package that has a semiconductor chip stacked on the film substrate of semiconductor packages according to the present invention.

FIG. 9B is a cross-sectional view showing the portion of the semiconductor package taken along the line VI-VI′ in FIG. 9A.

FIG. 10A is a cross-sectional view showing yet another embodiment of a semiconductor package that has a semiconductor chip stacked on the film substrate of semiconductor packages according to the present invention.

FIG. 10B is a cross-sectional view showing the portion of the semiconductor package taken along the line VII-VII′ in FIG. 10A.

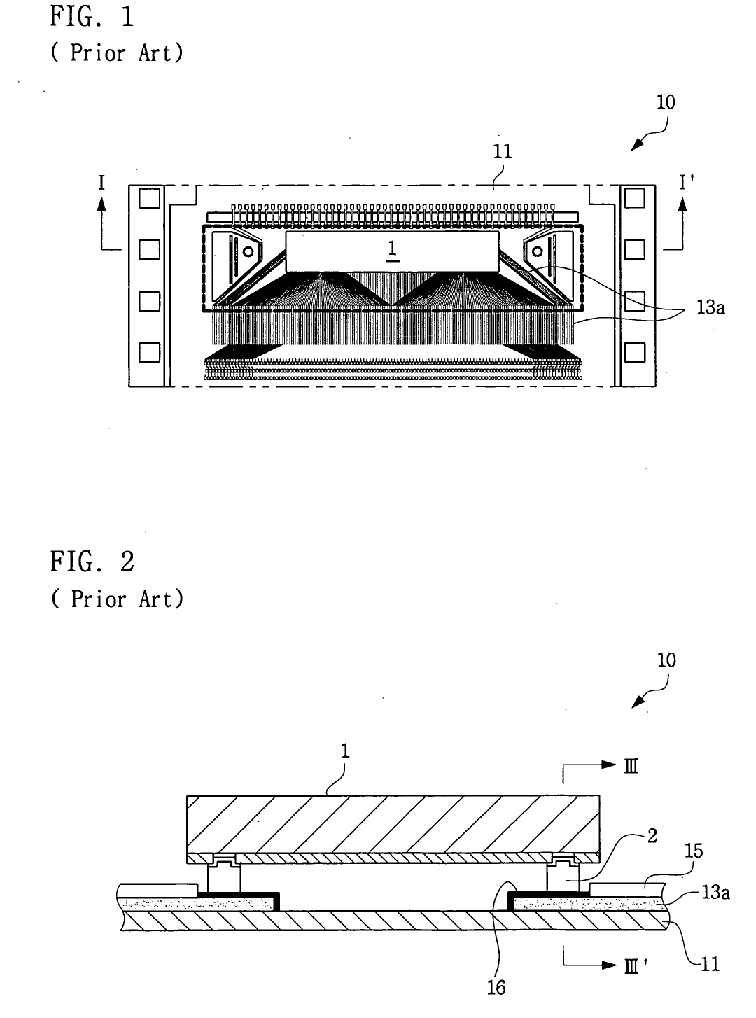

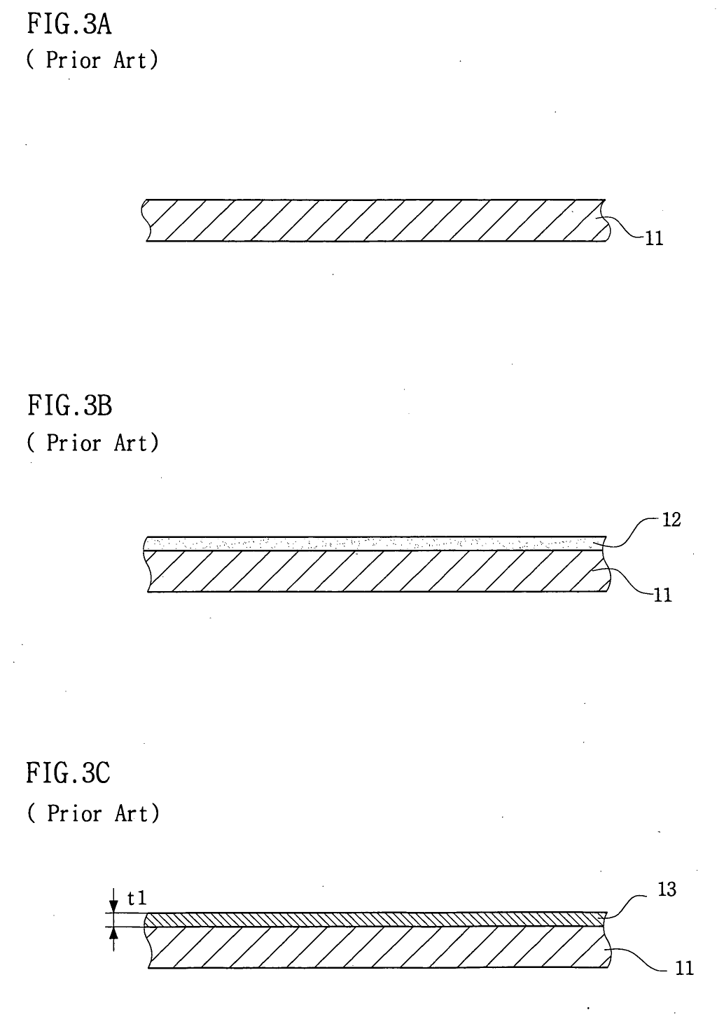

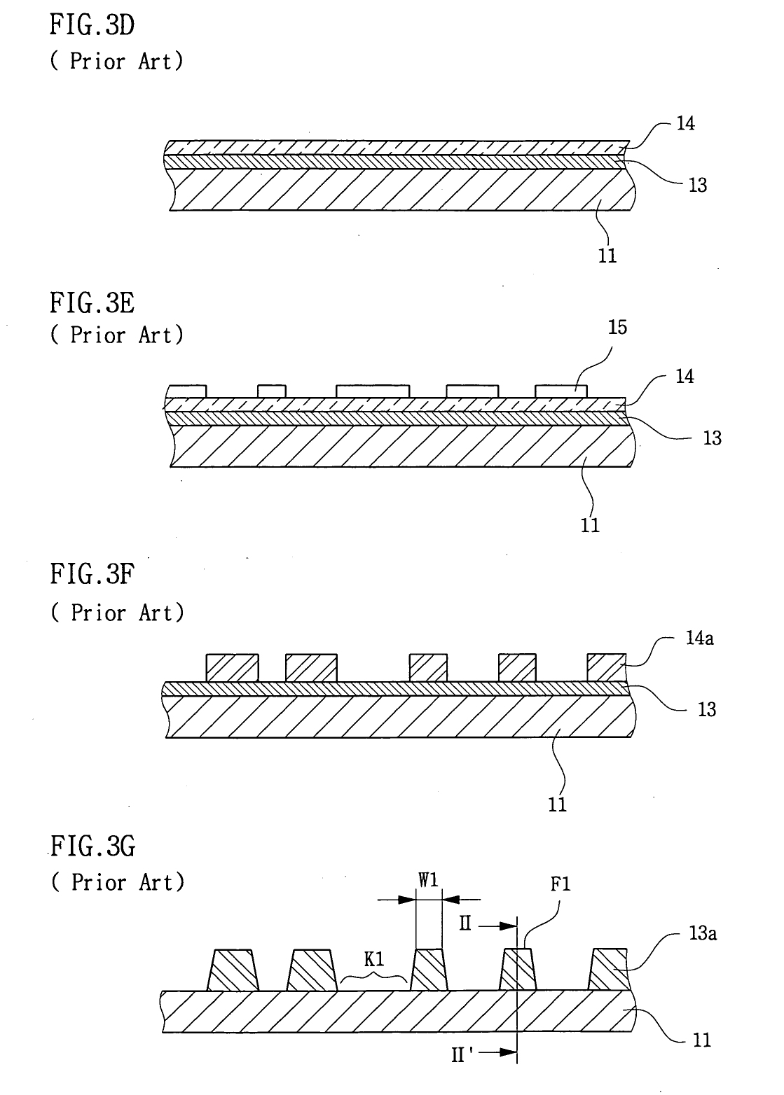

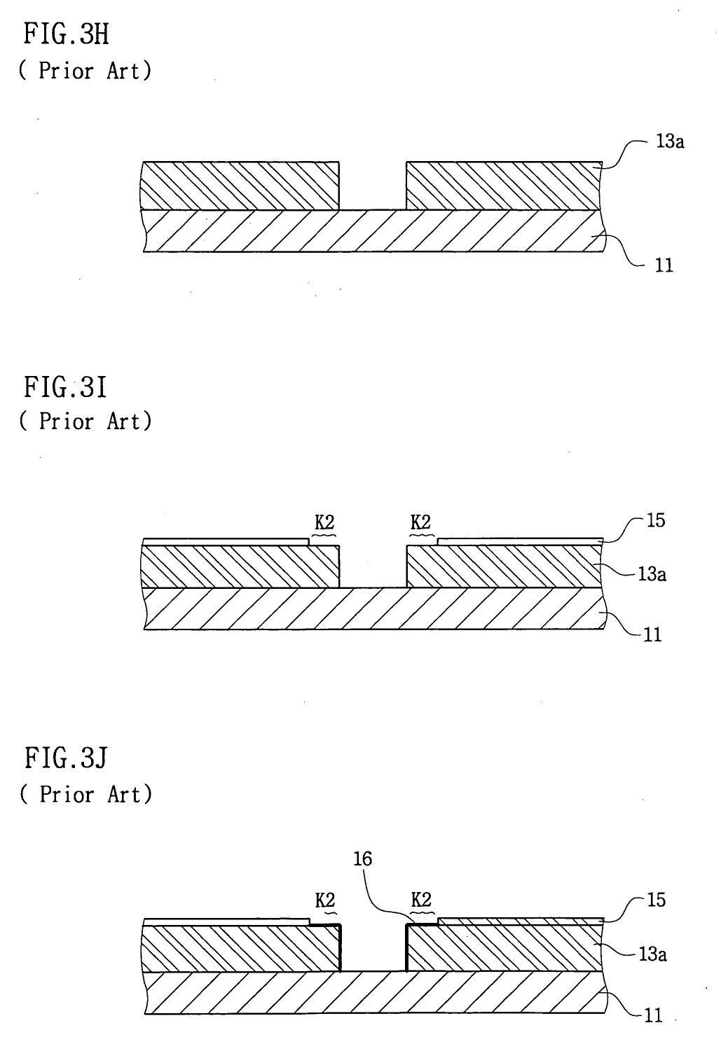

### DETAILED DESCRIPTION OF EXEMPLARY EMBODIMENTS OF THE INVENTION

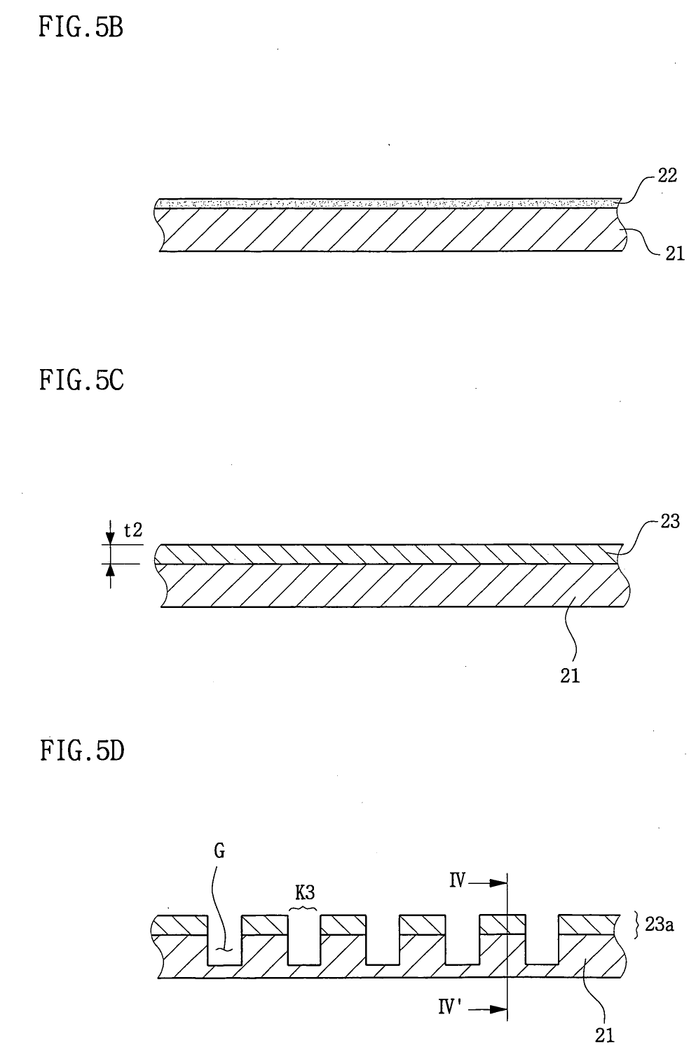

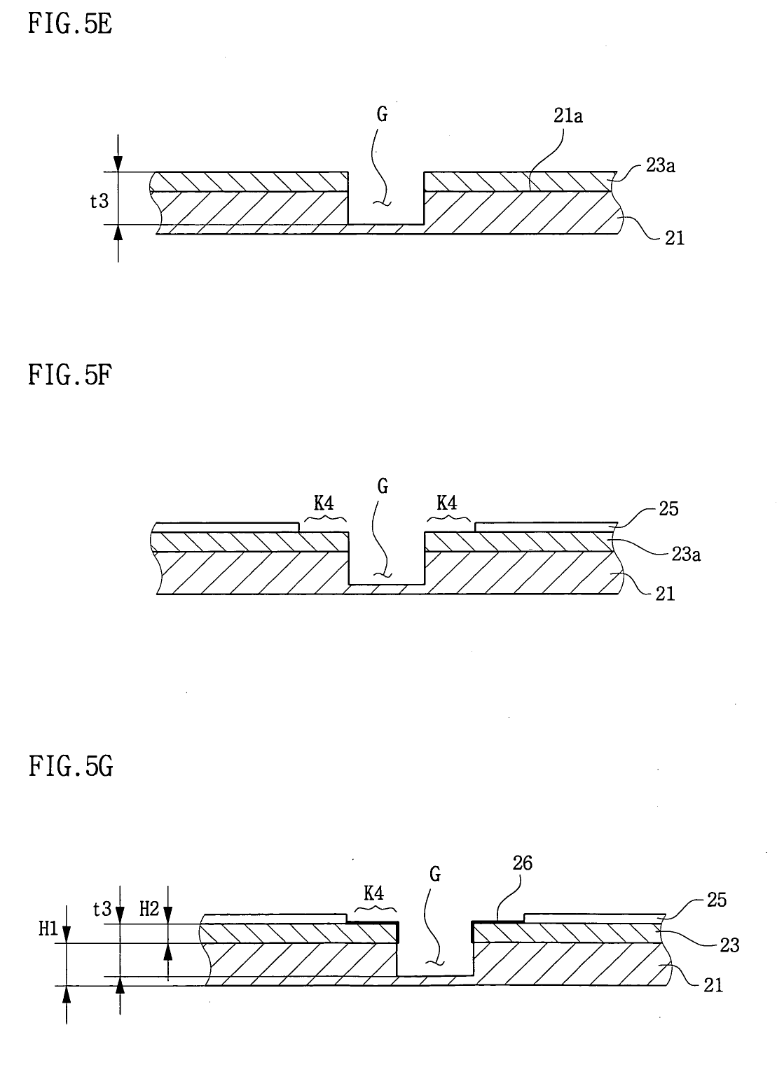

FIGS. 5A to 5G are cross-sectional views showing a manufacturing process for a film substrate of semiconductor packages according to the present invention.

As shown in FIG. 5A, a thin film insulating substrate 21 made with a polyimide resin material is provided. It is preferable to manufacture the thin film insulating substrate 21 by using material possessing good insulation, thermal shock, and elasticity characteristics. The material of the thin film insulating substrate 21 is not limited to polyimide. A suitable thickness of the thin film insulating substrate 21 is in the range of about 30-50 μm.

As shown in FIG. 5B, a metal seed layer 22 is formed by sputtering on the insulating substrate 21. The metal seed layer 22 is made with one or more materials selected from nickel (Ni), chromium (Cr), and copper (Cu).

Next, as shown in FIG. 5C, a copper metal layer 23 is formed by plating copper on the metal seed layer 22. Another conductor, other than copper may be used. For the convenience of illustration, the copper metal layer 23 is drawn to include the metal seed layer (22 in FIG. 5B), because the thickness of the metal seed layer is much smaller than the copper metal layer 23. Here, the thickness t2 of the copper metal layer 23 is about 1˜5 μm, and is thinner than that of the prior art. After the copper plating, soft-etching may be applied to the copper metal layer 23 to adjust the thickness t2 and to remove any oxidation layer of the surface.

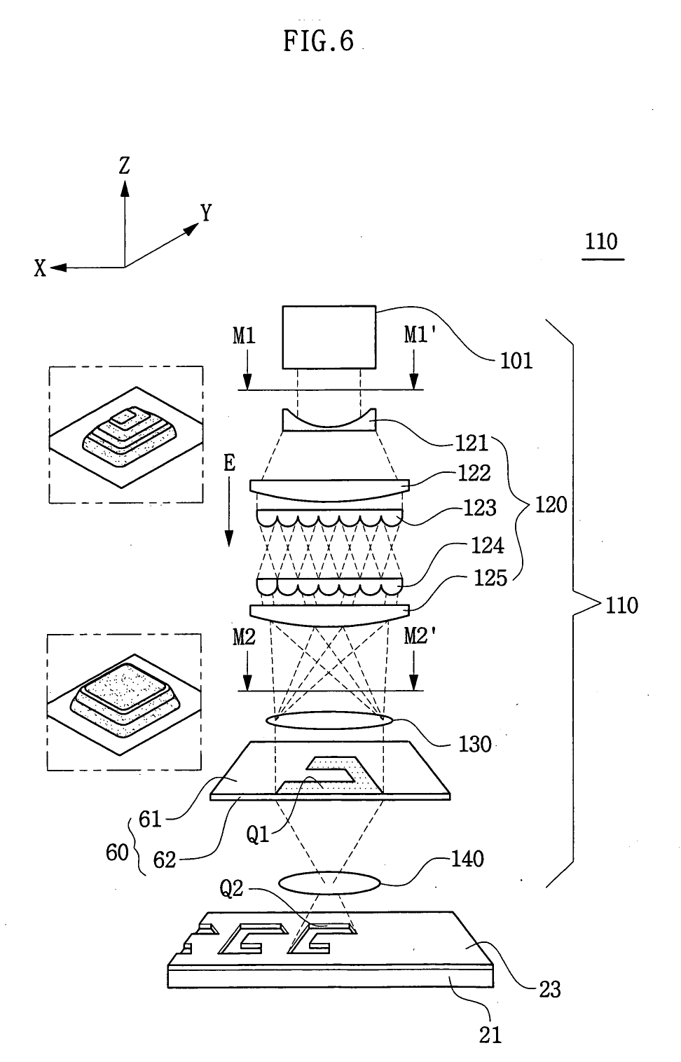

In FIG. 5D, a thin copper circuit pattern 23a and an inter-pattern groove G are formed by applying laser machining to the copper metal layer 23 and the thin film insulating substrate 21. This laser machining is explained later in detail with reference to FIG. 6.

FIG. 5E is a cross-sectional view along the line IV-IV′ in FIG. 5D. As shown in this figure and in FIG. 5D, the thin copper circuit pattern 23a is stacked on the thin film insulating substrate 21, and the inter-pattern groove G is formed by removing designated sections of the copper metal layer 23 and the thin film insulating substrate 21. A suitable depth t3 of the inter-pattern groove G is in the range of 8˜15 μm.

Next, as shown in FIG. 5F, solder resist is coated to form a solder resist layer 25 on the thin copper circuit pattern 23a. The solder resist layer 25 may be formed on the area (K3 in FIG. 5D) of the thin film insulating substrate 21 exposed between the thin copper circuit patterns 23a, but it is not formed on the area K4 to which a bump of a semiconductor chip will be connected.

Finally, as shown in FIG. 5G, a plating layer 26 is formed on the exposed area K4 of the thin copper circuit pattern 23a. The plating layer 26 is provided to improve characteristics of the contact with the bump of a semiconductor chip, and is commonly plated with tin (Sn). With this, the manufacturing process for the film substrate of a semiconductor package according to the present invention is complete. In the present embodiment, the solder resist layer 25 is formed prior to the formation of the plating layer 26, but the solder resist layer 25 may be formed after the plating layer 26 is formed on the thin copper circuit pattern 23a.

FIG. 6 is a schematic view illustrating a laser machining apparatus for manufacturing film substrates of semiconductor packages according to the present invention.

As shown in FIG. 6, the laser machining apparatus 100 comprises an optical system 110 to radiate a laser beam to the copper metal layer 23 and the thin film insulating substrate 21, and a stage (not shown) to hold the thin film insulating substrate 21.

The optical system 110 comprises a laser beam emitter 101, a beam homogenizer 120, a condenser lens 130, and a projection optical unit 140. The laser beam emitter 101 emits a laser beam. The beam homogenizer 120 homogenizes the laser beam emitted by the laser beam emitter 101. The condenser lens 130 condenses and collimates the laser beam coming through the beam homogenizer 120. The projection optical unit 140 projects the laser beam coming through the condenser lens 130 and a pattern mask 60 in sequence onto the copper metal layer 23.

The laser beam emitter 101 may be a KrF excimer laser device emitting a beam with a wavelength of 256 nm or an ArF excimer laser device emitting a beam with wavelength of 193 nm, for example.

The beam homogenizer 120 transforms a laser beam having a gaussian beam profile to a laser beam having a rectangular beam profile on the plane perpendicular to the direction E of laser beam emission. Namely, as shown in correspondence with the line M1-M1′ in FIG. 6, the beam having a gaussian beam profile, which has high intensity at the central region and rapidly decreasing intensity with increasing distance from the center, is transformed into the beam having a rectangular beam profile, which has uniform intensity across the entire region, as shown in correspondence with the line M2-M2′ in FIG. 6.

The beam homogenizer 120 comprises a concave lens 121, a convex lens 122, a first fly-eye lens 123, a second fly-eye lens 124, and a relay lens 125. The concave lens 121 diverges the laser beam emitted by the laser beam emitter 101. The convex lens 122 collimates the diverging laser beam. The first fly-eye lens 123, composed of many small lenses, causes the laser beam coming from the convex lens 122 to have a uniform intensity. The second fly-eye lens 124, composed of lenses that are bigger than those of the first fly-eye lens 123, increases the uniformity of the laser beam intensity further. The relay lens 125 collimates the laser beam coming from the second fly-eye lens 124.

The condenser lens 130 concentrates the laser beam coming from the relay lens 125 onto a patterned region Q1 of the pattern mask 60.

The projection optical unit 140 projects the laser beam coming through the pattern mask 60 onto the copper metal layer 23. The magnification of a pattern image Q2 on the copper metal layer 23 to the patterned region Q1 of the pattern mask 60 is determined according to the height of the corresponding lens of the projection optical unit 140. This magnification is determined by considering the wavelength of the laser beam and the pattern pitch of the thin copper circuit pattern (23a in FIG. 2D) to be formed on the copper metal layer 23.

Considering the fact that the laser irradiation region is significantly smaller than the upper surface of the copper metal layer 23, it is preferable that the stage (not shown) comprises a moving mechanism to move the thin film insulating substrate in the perpendicular x and y-axis directions on a plane that is perpendicular to the direction E of the laser irradiation.

As shown in FIG. 6, the pattern mask 60 comprises a quartz plate 62, through which the laser beam directly passes, and a chromium (Cr) pattern film 61 on the quartz plate. On the chromium (Cr) pattern film 61, the patterned region Q1 is provided in correspondence with the thin copper circuit pattern (23a in FIG. 2D).

Hereinafter, the laser machining on the copper metal layer (23 in FIG. 5C) and the thin film insulating substrate (21 in FIG. 5C) is explained in detail. It is assumed that the laser beam emitter (101 in FIG. 6) is a KrF excimer laser device emitting a beam with a wavelength of 256 nm, and the thin film insulating substrate (21 in FIG. 5C) is made with polyimide.

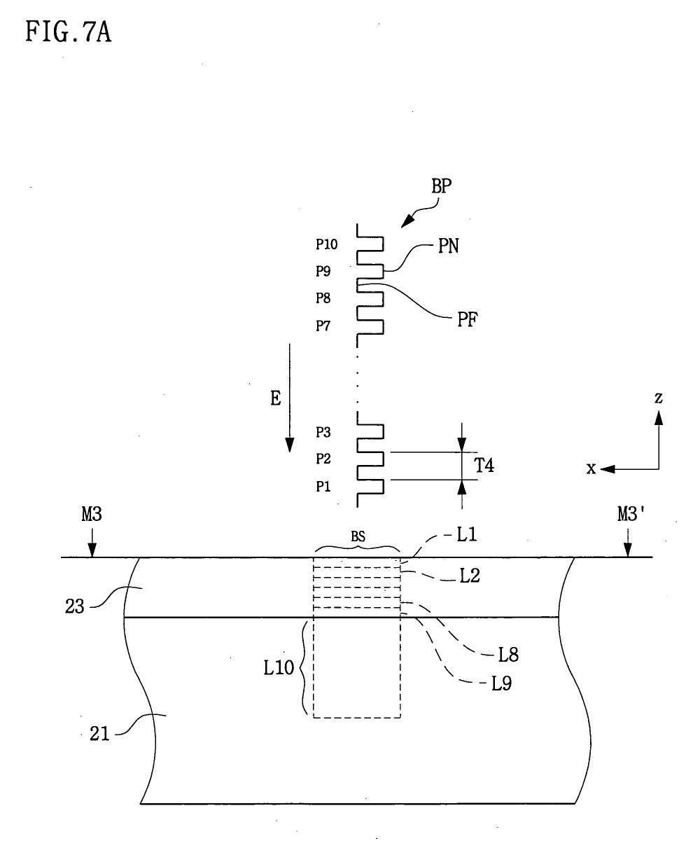

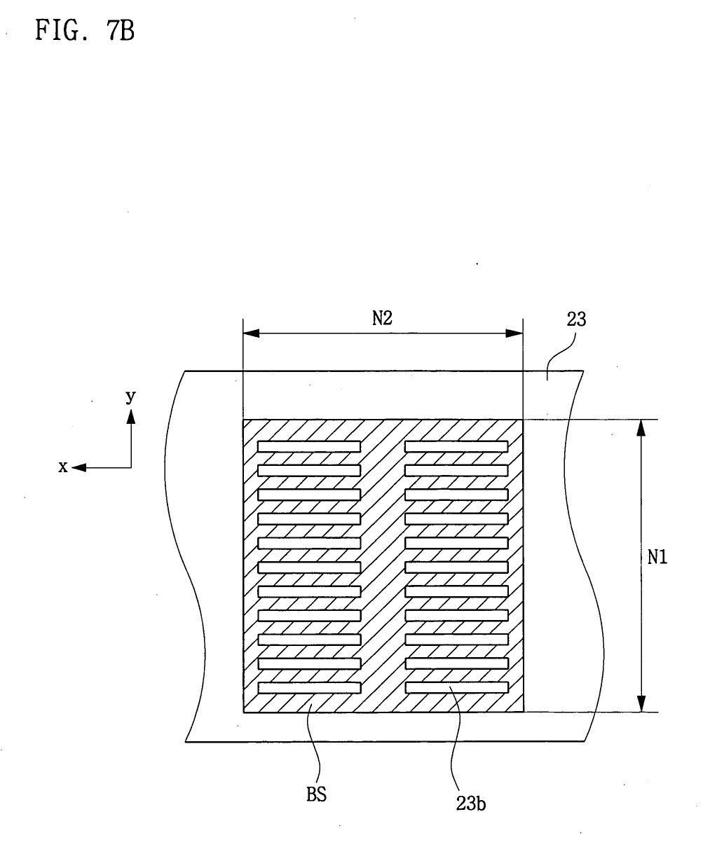

FIG. 7A is a schematic view illustrating the laser machining in a method of manufacturing film substrates of semiconductor packages according to an embodiment of the present invention. FIG. 7B is a top view showing the irradiation region of an area that includes the line M3-M3′ in FIG. 7A.

As shown in FIG. 7A, the laser beam consists of a laser pulse (BP) with a frequency of 50 Hz emitted by the KrF excimer laser device (not shown) and passed through an optical system such as the optical system 110. The energy of the laser beam per unit area on the copper metal layer 23 is 8 J/cm². For the convenience of illustration, the laser pulse BP is shown to be composed often pulses P1 to P10. The period T4 of the laser pulse BP can be calculated to be 1/50 second. The laser pulse BP is turned on and off by a Q-switch, or the like (not shown) in the KrF excimer laser device (not shown). As shown in FIG. 7A, the laser pulse BP has repeated pulse-on PN and pulse-off PF periods. In the case of a laser beam with an energy of 8 J/cm², the copper metal layer 23 is removed, by ablation, at a rate of about 1 μm per pulse, and the thin film insulating substrate 21 made with polyimide is at a rate of about 10 μm per pulse. For reference, in the case of a laser beam with energy of 7 J/cm², the copper metal layer 23 is removed at a rate of about 0.9 μm per pulse, and the thin film insulating substrate 21 made with polyimide is at a rate of about 8 μm per pulse.

For example, as shown in FIG. 7A, let the thickness of the copper metal layer 23 be 9 μm and the energy of the laser beam 8 J/cm². Then the entire thickness of 9 μm in the copper metal layer 23 will be removed, because a first to a ninth ablation-cycle thickness, labeled as L1 to L9 in FIG. 7A are removed in response to the first to the ninth pulses P1 to P9, respectively. Then, a thickness of 10 μm of the thin film insulating substrate 21 is removed, because a tenth ablation-cycle thickness L10 therein is removed in response to a tenth pulse P10. Here, each one of the first to ninth ablation-cycle thicknesses L1 to L9 is 1 μm, and the tenth ablation-cycle thickness L10 is 10 μm. Hence, the amount of ablation in the copper metal layer 23 and thin film insulating substrate 21 can be controlled by adjusting the energy per unit area and pulse frequency of the laser beam.

As explained above, the number of laser pulses BP needed for the laser machining of the copper metal layer 23, which we will call the first pulse number, is given by the expression: the first pulse number=the thickness of the copper metal layer 23/a first ablation-cycle thickness, where the first ablation-cycle thickness is the thickness of the copper metal layer 23 that is removed per laser pulse period T4 (corresponding to one of L1 to L9, in this example).

Multiplying the first pulse number by the length of time corresponding to the pulse-on PN of the laser pulse BP gives a first exposure time, the length of time for exposing the copper metal layer 23 to the laser beam.

In the same manner, a second pulse number, the number of laser pulses BP needed for the laser machining of the thin film insulating substrate 21, is given by the expression: the second pulse number=the thickness of the thin film insulating substrate 21/a tenth ablation-cycle thickness L10, where the tenth ablation-cycle thickness is the thickness of the thin film insulating substrate 21 that is removed per laser pulse period T4.

Multiplying the second pulse number by the length of time corresponding to the pulse-on PN of the laser pulse BP gives a second exposure time, the length of time for exposing the thin film insulating substrate 21 to the laser beam.

For a given laser beam and time duration, the amount of ablation of the copper metal layer differs greatly from that of the thin film insulating substrate. For instance, in the example above it was 1 μm and 10 μm, respectively. Hence it may be desirable to apply different laser energy levels or pulse frequencies to different materials.

The ablation of the copper metal layer 23 and the thin film insulating substrate 21 includes melting and evaporating these materials with the laser beam, and this debris of gases and particles may be left in the work area. After laser machining in a chamber, it is possible to remove the debris from the chamber via a purge process, where inert gases such as helium (He) or argon (Ar) are fed into the chamber.

As shown in FIG. 7B, the patterned region Q1 of the pattern mask 60 throws an image of the laser beam on the copper metal layer 23. An irradiation area BS, where the copper metal layer 23 is irradiated by the laser beam, may have a first length N1 of about 35 mm and a second length N2 of about 40 mm. The irradiation area BS is divided into two types of regions. One type is shielded from the laser beam by the pattern mask 60 and the thin copper circuit pattern 23a is formed thereon. The other type is irradiated by the laser beam passing through the pattern mask 60 and the inter-pattern groove G is formed thereon. After finishing the laser machining of the irradiation area BS, the thin film insulating substrate 21 having the copper metal layer 23 stacked thereon may be shifted left along the x-axis by the stage (not shown). The thin film insulating substrate 21 having the copper metal layer 23 stacked thereon may be long and thin-film shaped, so it may be kept on a roll, like a roll of camera film. For instance, it may be released by unwinding the roll, be processed by the laser machining apparatus 100, and then be wound by a winding roll (not shown). In this case, the position of the thin film insulating substrate 21 is shifted by the revolving force of the winding-unwinding rolls, as an alternative to an x-y stage, for example.

In the present embodiment, as shown in FIG. 6, the laser machining apparatus 100 employed the pattern mask 60. Without the pattern mask, however, the thin copper circuit pattern 23a and the inter-pattern groove G may be formed by directly processing the copper metal layer 23 and the thin film insulating substrate 21 with a focused laser beam. For example, an Nd-YAG laser with wavelength of 355 nm may be utilized.

Hereinafter, the structure of the film substrate of semiconductor packages according to an embodiment of the present invention is explained in detail.

As shown in FIG. 5G, the film substrate of a semiconductor package includes the thin film insulating substrate 21 made with polyimide and the thin copper circuit pattern 23a formed on the thin film insulating substrate 21. The depth t3 of the inter-pattern groove G between the thin copper circuit patterns 23a is deeper than the thickness H2 of the thin copper circuit pattern 23a. This is an obvious result of the fact that the thin film insulating substrate 21 is also treated by the laser machining apparatus shown in FIG. 6.

In this embodiment it is preferable that the thickness H2 of the thin copper circuit pattern 23a is in the range of 15 μm, which is thinner than usual, for efficient laser machining. The thin film insulating substrate 21 may have its thickness H1 in the range of 30˜50 μm to be sufficiently thin and also to adequately support the thin copper circuit pattern 23a. Ignoring the depth of the plating layer 26, the inter-pattern groove G has its depth t3 in the range of 8˜15 μm and preferably not exceeding 15 μm to allow the thin film insulating substrate 21 to adequately support the thin copper circuit pattern 23a.

A solder resist layer 25 is formed on the thin copper circuit pattern 23a, and a plating layer 26 is formed on the area K4 of the thin copper circuit pattern 23a exposed by the solder resist layer 25. In terms of manufacturing costs and characteristics of contact with bumps of a semiconductor chip, it is preferable that the plating layer 26 is made with tin (Sn).

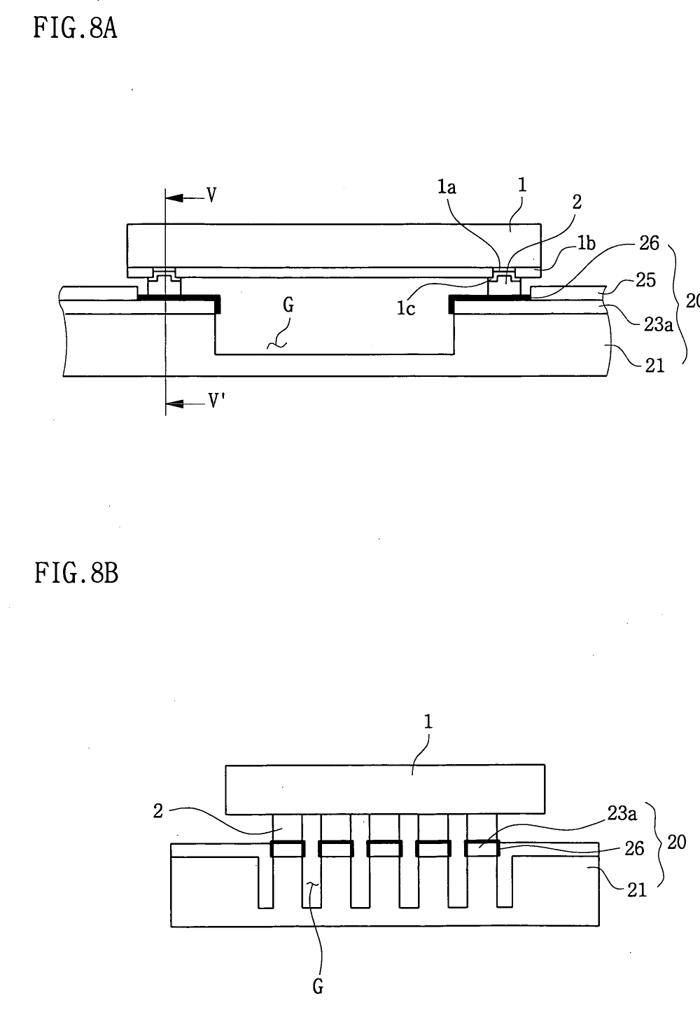

FIG. 8A is a cross-sectional view showing an embodiment of a semiconductor package that has a semiconductor chip stacked on the film substrate of the semiconductor package according to the present invention. FIG. 8B is a cross-sectional view showing the portion of the semiconductor package taken along the line V-V′ in FIG. 8A, but the solder resist layer is not shown for the convenience of illustration.

A structure of normal inner lead bonding, where bumps 2 provided at the backside of a semiconductor chip 1 are mounted on a film substrate 20, is shown in FIGS. 8a and 8b. The bump 2 is attached to the plating layer 26 on the thin copper circuit pattern 23a. Here, a UBM (under bump metallization) layer 1c is formed on a chip pad 1a exposed by a passivation layer 1b, and the bump 2 is formed on the UBM layer 1c of the semiconductor chip 1. It is preferable that the bump 2 includes gold (Au) to improve contact characteristics with the plating layer 26.

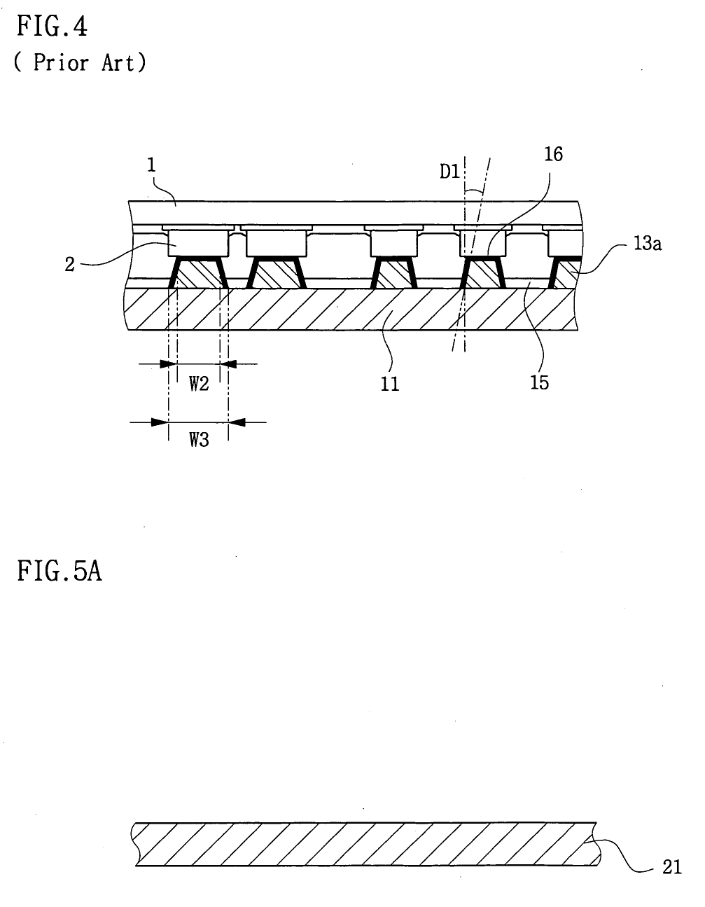

The film substrate of the semiconductor package according to the embodiments of the present invention has the structure of a film substrate of a COF (chip on film) package. In particular, as shown in FIG. 8B, the contact area between the bump 2 and the plating layer 26 on the thin copper circuit pattern 23a is wider than that of the prior art. This comparison can be made by observing the contact area between the bump 2 and the plating layer 26 on the thin copper circuit pattern 23a in the prior art shown in FIG. 4. This improves characteristics of the electric contact between the bump 2 and the thin copper circuit pattern 23a.

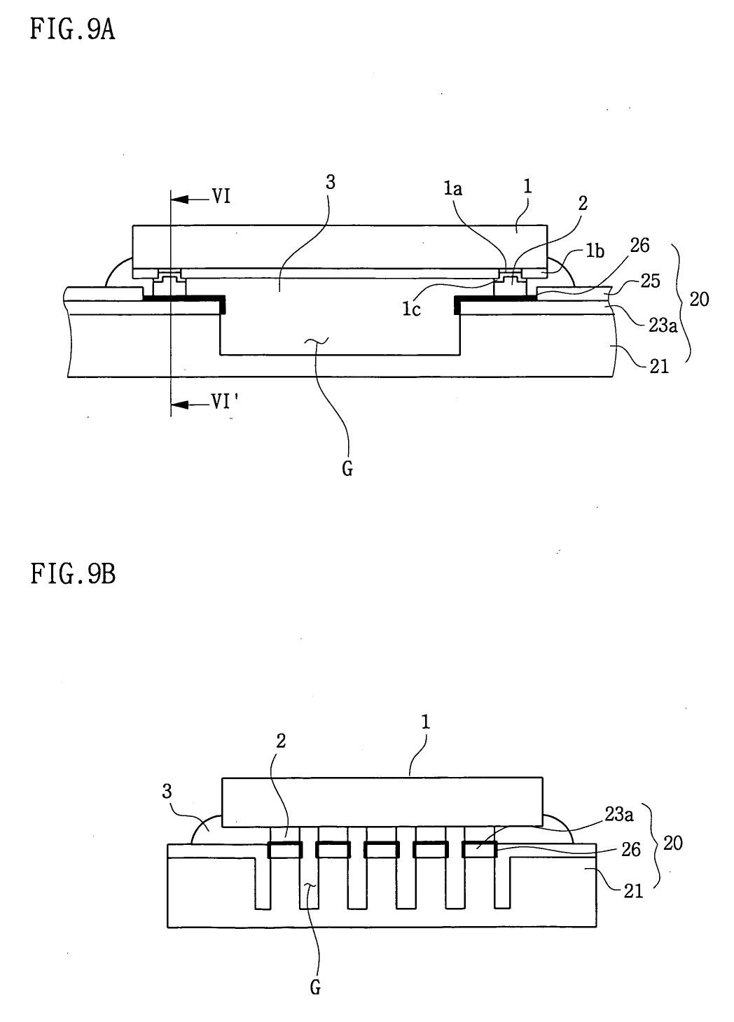

FIG. 9A is a cross-sectional view showing another embodiment of a semiconductor package that has a semiconductor chip stacked on the film substrate of the semiconductor package according to the present invention. FIG. 9B is a cross-sectional view showing the portion of the semiconductor package taken along the line VI-VI′ in FIG. 9A, but the solder resist layer is not shown for the convenience of illustration.

In FIGS. 9a and 9b, a structure of NCP (non conductive paste) bonding is shown, where bumps 2 provided at the backside of a semiconductor chip 1 are mounted on a plating layer 26 of a film substrate 20, and the bump 2 and the backside of the semiconductor chip 1 are sealed with a sealant 3 that may be a non-conductive paste, an epoxy, a thermo-setting resin, or the like.

Owing to the inter-pattern groove G formed by the laser machining of the copper metal layer 23 and the thin film insulating substrate 21, the space between the backside of the semiconductor chip 1 and the thin film insulating substrate 21 tends to be wider than in conventional methods. This increased space allows sealant material, which may be applied in liquid form, to be hardened afterwards by heat or other curing, to flow easier during sealant formation and widens the contact area between the sealant 3 and the thin film insulating substrate 21, and thereby improves the resistance of semiconductor packages to external shock owing to the tighter inter-coupling between the semiconductor chip 1, the film substrate 20, and the sealant 3.

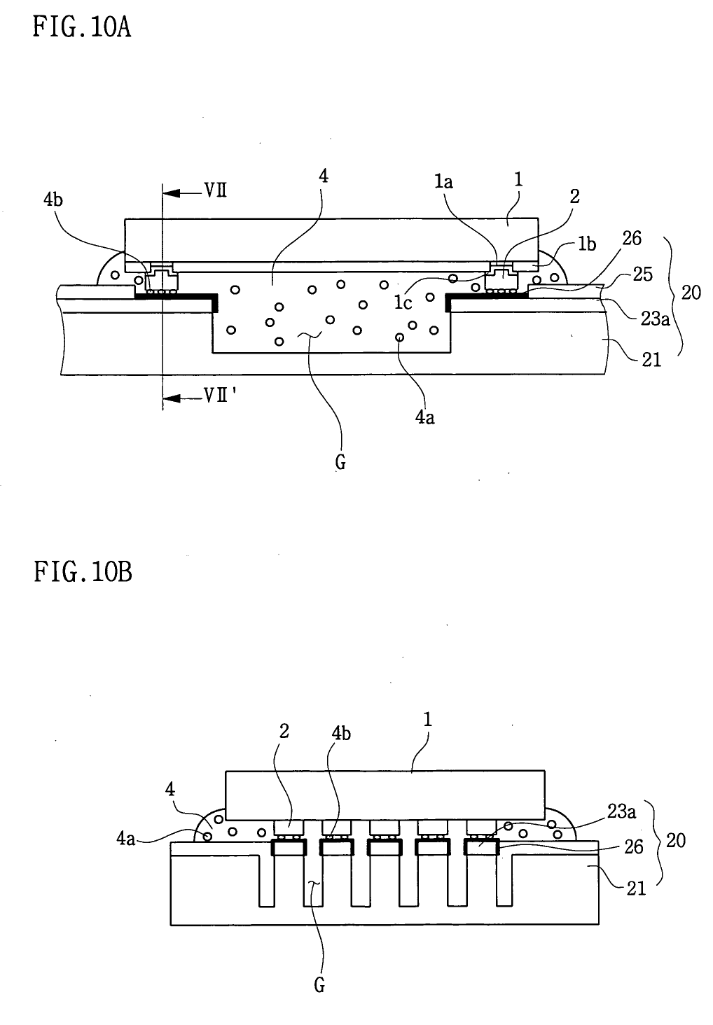

FIG. 10A is a cross-sectional view showing yet another embodiment of a semiconductor package that has a semiconductor chip stacked on the film substrate of the semiconductor package according to the present invention. FIG. 10B is a cross-sectional view showing the portion of the semiconductor package taken along the line VII-VII′ in FIG. 10A, but the solder resist layer is not shown for the convenience of illustration.

In FIGS. 10A and 10B, a structure of ACF (anisotropic conductive film) bonding is shown, where bumps 2 provided at the backside of a semiconductor chip 1 are mounted on a plating layer 26 of a film substrate 20, and the bump 2 and the backside of the semiconductor chip 1 are sealed with a sealant 4 including therein a conductive paste, a conductive epoxy, a conductive thermo-setting resin, or the like. In the preferred embodiment shown, however, the sealant 4 contains conductive particles 4a, which may comprise a sphere-shaped polymer and a conductive film enclosing the sphere-shaped polymer. This conductive film is made with nickel Ni and/or gold (Au). The conductive particles 4a are about 3˜7 μm in diameter. In the present embodiment, a subset of conductive particles 4b are between the bump 2 and the plating layer 26. These conductive particles 4b make direct contact with the bump 2 and the plating layer 26 causing an improved electrical contact between the bump 2 and the thin copper circuit pattern 23a. The other conductive particles 4a are dispersed with a relatively low density so that they rarely touch each other in the matrix, and therefore the overall sealant stays non-conductive.

For the convenience of illustration, the bump 2 and the plating layer 26 are shown to be separated a little by the conductive particles 4b. In reality, applied force between the semiconductor chip 1 and the bump 2 may imbed the conductive particles 4b into, and between, the bump 2 and the plating layer 26, thereby allowing the bump 2 to electrically contact the plating layer 26. Some of these conductive bumps 4b may be deformed in the process.

As mentioned above, owing to the inter-pattern groove G formed by the laser machining of the copper metal layer 23 and the thin film insulating substrate 21, the space between the backside of the semiconductor chip 1 and the thin film insulating substrate 21 tends to be wider than in conventional methods. Even if the conductive particles 4b clump together to form large groups when the sealant 4 is made, this increased space plays a role of improving the positioning stability and electrical connectivity of the semiconductor chip 1, and makes sealant 4 containing conductive particles 4a easily available for the manufacture of thin film substrates.

The film substrate of semiconductor packages and the manufacturing method thereof according to embodiments of the present invention have the following advantages. The adoption of a laser machining in forming the thin copper circuit pattern has solved an over-etching problem at the upper part of the thin copper circuit pattern, which is frequently found in conventional wet-etching methods of the copper metal layer. Consequently, the contact area between the bump and the thin copper circuit pattern is increased, improving electric contact characteristics therebetween.

In addition, embodiments of the present invention improve efficiency and lower maintenance costs in manufacturing processes for the film substrate by adopting a simple laser machining to form the thin copper circuit pattern in lieu of a traditional wet-etching process undergoing complex lithography steps such as photoresist coating, exposing, developing, etching, and photoresist stripping.

What is claimed is:

1. A film substrate of a semiconductor package comprising:
a thin film insulating substrate made with a resin material; and
a circuit pattern formed on the thin film insulating substrate, wherein the depth of an inter-pattern groove between the circuit patterns is greater than the thickness of the circuit pattern.

2. The film substrate of claim 1, wherein the thin film insulating substrate is made with polyimide, and the circuit pattern comprises a thin copper circuit pattern.

3. The film substrate of claim 1, wherein the thickness of the circuit pattern is in the range of 1˜5 μm.

4. The film substrate of claim 1, further comprising a non-conductive material that fills the inter-pattern groove

5. The film substrate of claim 1, further comprising a material that fills the inter-pattern groove that includes randomly distributed conductive spheres.

6. The film substrate of claim 1, wherein the depth of the inter-pattern groove is in the range of 8˜15 μm.

7. The film substrate of claim 1, wherein a solder resist layer is formed on the circuit pattern, and a plating layer is formed on an area of the circuit pattern exposed by the solder resist layer.

8. The film substrate of claim 7, wherein the plating layer comprises tin (Sn).

9. A method of manufacturing a film substrate of a semiconductor package, comprising:
providing a thin film insulating substrate made with a resin material;
forming a metal layer on the thin film insulating substrate; and
forming a circuit pattern by treating the metal layer with a laser.

10. The method of claim 9, wherein the thin film insulating substrate is made with polyimide.

11. The method of claim 9, wherein the metal layer comprises copper (Cu).

12. The method of claim 9, wherein the forming the circuit pattern comprises:
placing a pattern mask above the metal layer;
forming the circuit pattern by exposing the metal layer, having a thickness, during a first exposure time to a laser beam passing through an opening of the pattern mask; and
forming an inter-pattern groove by exposing the thin film insulating substrate, having another thickness, during a second exposure time to the laser beam passing through the opening of the pattern mask.

13. The method of claim 12, wherein the pattern mask comprises a quartz plate and a chromium (Cr) pattern film on the quartz plate.

14. The method of claim 12, wherein the laser beam is pulsed with repeated pulse-on and pulse-off periods.

15. The method of claim 14, wherein the first exposure time is defined by the expression:
the first exposure time=(the thickness of the metal layer)/(a first ablated thickness of the metal layer treated during a pulse period of the laser beam)×(the pulse-on period).

16. The method of claim 14, wherein the second exposure time is defined by the expression:
the second exposure time=(the thickness of the thin film insulating substrate)/(a second ablated thickness of the thin film insulating substrate treated during a pulse period of the laser beam)×(the pulse-on period).

17. The method of claim 12, wherein the laser beam is either a beam with a wavelength of 256 nm emitted by a KrF excimer laser or a beam with a wavelength of 193 nm emitted by an ArF excimer laser.

18. The method of claim 17, wherein the frequency corresponding to the pulse period is substantially 50 Hz.

19. The method of claim 12, wherein the forming the circuit pattern and forming the inter-pattern groove are performed by a laser machining apparatus comprising an optical system to throw a laser beam image on the metal layer and the thin film insulating substrate.

20. The method of claim 19 further comprising a stage to hold the thin film insulating substrate.

21. The method of claim 19 wherein selected areas of the thin film insulating substrate with the metal layer, which is fixed on a spool, are exposed to the laser beam image by rotating the spool.

22. The method of claim 19, wherein the optical system comprises:
a laser beam emitter to emit a laser beam;
a beam homogenizer to homogenize the laser beam emitted by the laser beam emitter;
a condenser lens to condense and collimate the laser beam that transmits through the beam homogenizer; and
a projection optical unit to project the laser beam that transmits through the condenser lens and the pattern mask in sequence onto the metal layer and the thin film insulating substrate.

23. The method of claim 22, wherein the beam homogenizer comprises one or more fly-eye lenses.

24. The method of claim 20, wherein the stage comprises a moving mechanism to move the thin film insulating substrate in mutually perpendicular x and y-axis directions on a plane that is perpendicular to the direction of the laser irradiation.

25. A method of manufacturing an electrical connection between a film substrate and a semiconductor chip, comprising:
forming a conductive layer on the film substrate;
laser over-etching the conductive layer to form a circuit pattern within the conductive layer and an aligned etch pattern in the film substrate;
providing bumps on the semiconductor chip; and
mounting the semiconductor chip onto the film substrate via the bumps and the circuit pattern.

26. The method of claim 25, wherein the laser beam is pulsed with repeated pulse-on and pulse-off periods.

27. The method of claim 25, wherein the first exposure time is defined by the expression:
the first exposure time=(the thickness of the metal layer)/(a first ablated thickness of the metal layer treated during a pulse period of the laser beam)×(the pulse-on period).

28. The method of claim 25, wherein the second exposure time is defined by the expression:
the second exposure time=(the thickness of the thin film insulating substrate)/(a second ablated thickness of the thin film insulating substrate treated during a pulse period of the laser beam)×(the pulse-on period).

29. The method of claim 25, wherein the laser beam is either a beam with a wavelength of 256 nm emitted by a KrF excimer laser or a beam with a wavelength of 193 nm emitted by an ArF excimer laser.

30. The method of claim 29, wherein the frequency corresponding to the pulse period is substantially 50 Hz.

31. The method of claim 25, wherein the laser etching is performed by a laser machining apparatus comprising an optical system to throw a laser beam image on the metal layer and the thin film insulating substrate, the optical system comprising:
a laser beam emitter to emit a laser beam;
a beam homogenizer to homogenize the laser beam emitted by the laser beam emitter;
a condenser lens to condense and collimate the laser beam that transmits through the beam homogenizer; and
a projection optical unit to project the laser beam that transmits through the condenser lens and the pattern mask in sequence onto the metal layer and the thin film insulating substrate.
